(19) United States
(12) Patent Application Publication
(10) Pub. No.: US 2009/0250780 A1
(43) Pub. Date: Oct. 8, 2009

(54) HIGH FILL-FACTOR LASER-TREATED SEMICONDUCTOR DEVICE ON BULK MATERIAL WITH SINGLE SIDE CONTACT SCHEME

(75) Inventor: Neal T. Kurfiss, Waltham, MA (US)

Correspondence Address: PEPPER HAMILTON LLP, ONE MELLON CENTER, 50TH FLOOR, 500 GRANT STREET, PITTSBURGH, PA, 15219, US

(73) Assignee: SIONYX, INC., Beverly, MA (US)

(21) Appl. No.: 12/399,827

(22) Filed: Mar. 6, 2009

Related U.S. Application Data
(60) Provisional application No. 61/034,313, filed on Mar. 6, 2008.

(51) Int. Cl. H01L 31/0352; H01L 31/02

(52) U.S. Cl. 257/443; 257/464; 438/98; 257/E31.032; 257/E31.11

(57) ABSTRACT

The present disclosure provides systems and methods for configuring and constructing a single photo detector or array of photo detectors with all fabrications circuitry on a single side and an architecture that enables the laser step to be the final step or a late step in the fabrication process. Both the anode and the cathode contacts of the diode are placed on a single side, while a layer of laser treated semiconductor is placed on the opposite side for enhanced cost-effectiveness, photon detection, and fill factor.

### RELATED APPLICATIONS

The present application claims the benefit of U.S. provisional application No. 61/034,313 filed on Mar. 6, 2008, hereby incorporated by reference in its entirety.

### TECHNICAL FIELD

The present disclosure relates to laser treated semiconductor diode structure and design. In particular, the present disclosure relates to laser-treated semiconductor diodes with single side fabrication on bulk material.

### BACKGROUND

Current laser treated semiconductor diodes use a combination of top-side and back-side contact schemes. Combination designs require additional lithography steps following the laser step to place contacts on the top-side. The top side is generally the side of a photo-responsive semiconductor device that is exposed to a source of light or electromagnetic radiation of interest, for example in a sensor or detector device. The additional lithography following the laser step limits the number of fabrication houses that can produce laser treated semiconductor diodes, because many fabrication houses do not allow re-entry of partially processed material. In many cases, the company that performs the lithography is a different company than the company that performs the laser step and the steps are performed at separate locations.

In addition, fill factor is an important parameter in area array image detector performance. Combination designs by their very nature require that contacts be placed on the top side of the detector, taking up space that could be used by the laser treated semiconductor layer for photon detection thereby reducing fill factor.

### SUMMARY

In some embodiments, some or all of the traditional fabrication steps are completed before the laser processing step, allowing the laser step to become the final or a late step in the process. By making the laser step the final or a late step in the process, it would be unnecessary to insert partially processed material into a fabrication house, thereby increasing the amount of potential fabrication houses available to produce laser treated semiconductor diodes.

In some embodiments, vertically stacking the laser treated semiconductor above a silicon integrated circuit provides a greater fill factor, in some embodiments almost or at 100% fill factor, and enables the laser processing step to be the final step or a late step since all or substantially all electrical contacts are located on the back side of the device and no or little additional top-side structure is required.

In some embodiments, the resulting arrangement of the electromagnetic field lines and potentials within such a device provides advantageous design and operation characteristics.

### BRIEF DESCRIPTION OF THE DRAWINGS

FIG. 1 illustrates a cross sectional area of an exemplary embodiment of a laser treated semiconductor diode with back-side metal contact pads.

FIG. 2 illustrates a back view of a laser treated semiconductor diode with back-side metal contact pads.

FIG. 3 illustrates an exemplary array of laser treated semiconductor diodes with back-side metal contact pads.

FIG. 4 illustrates a cross sectional area of an exemplary embodiment of a laser treated semiconductor diode with back-side metal contact pads including an exemplary circuit diagram approximation of the diode in operation.

FIG. 5 illustrates an exemplary diagram of the field lines in a cross sectional area during operation of a laser treated semiconductor diode with back side metal contact pads.

### DETAILED DESCRIPTION

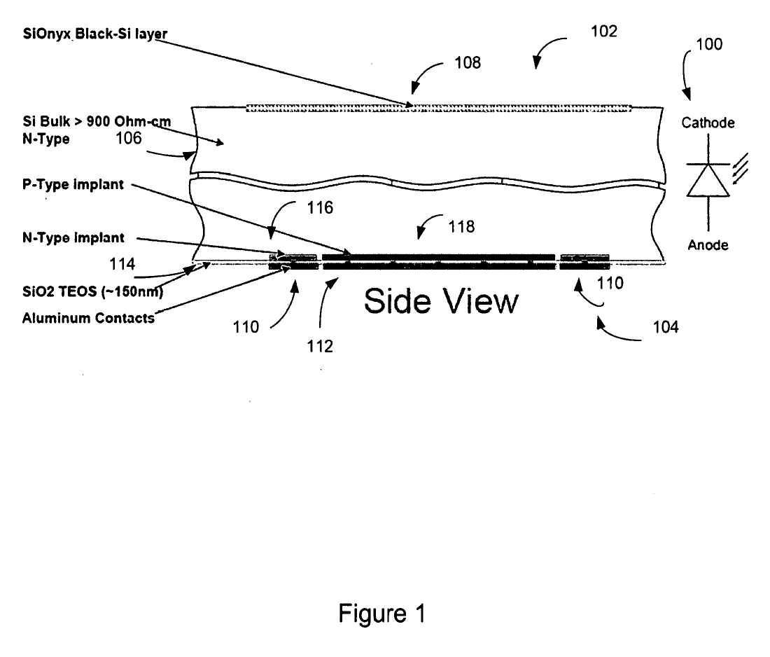

FIG. 1 illustrates a cross sectional area of an exemplary embodiment of a laser treated semiconductor diode 100 with back-side metal contact pads 110 and 112. In the exemplary embodiment, the laser treated semiconductor diode is an N-type diode, though persons skilled in the art will recognize that the diode 100 may be with other types (such as P-type, Schottky diodes, etc.). The exemplary laser treated semiconductor diode has a front 102 and a back 104 side. The exemplary laser treated semiconductor diode 100 contains a bulk layer of silicon 106 between the front 102 and the back 104 sides. The bulk layer 106 may be doped with N-type doping, depending on the doping of the laser treated layer 108. In the exemplary embodiment, the front 102 side is covered by a laser treated semiconductor layer 108 and connected to the bulk layer 106. The laser treated semiconductor layer 108 is photo active and has an increased sensitivity as compared to an undoped, untreated layer. The back 104 side may be connected to aluminum cathode 110 and anode 112 contacts and may be covered by a thin layer of SiO2 TEOS 114. The back 104 side may also be doped using N-Type dopants 1116 under the cathode contact 10 and P-type dopants 118 under the anode contact 112. In this embodiment, the laser treated semiconductor layer 108 on the front 102 side acts as a cathode, while the back 104 side P-type doped section 118 acts as an anode. Additionally, an embodiment is contemplated wherein the laser treated semiconductor diode 100 is devoid of ohmic contacts.

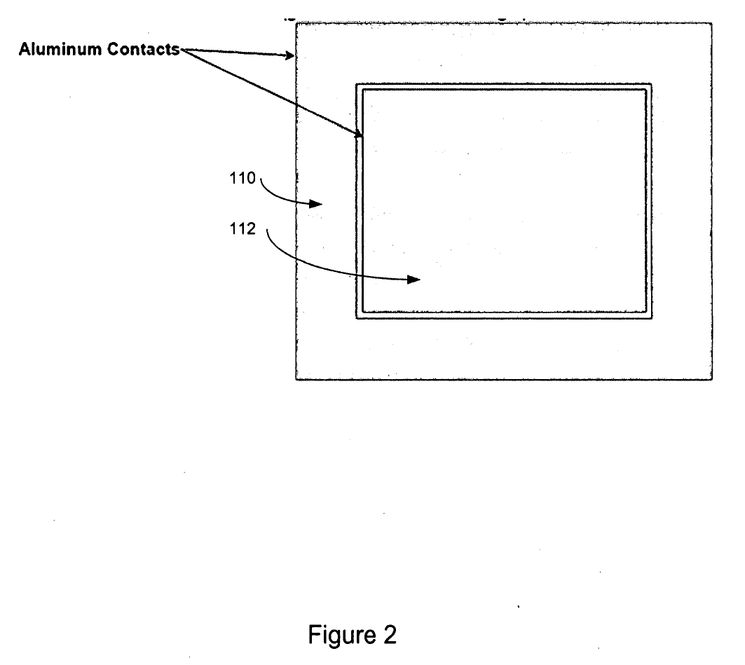

FIG. 2 illustrates a back view of a laser treated semiconductor diode 100 with back-side metal contact pads 110 and 112. In the exemplary embodiment, aluminum contacts 110 and 112 are coupled to the back side 104. The outer contact 110 is coupled to the N-type doping area of the back side 102 and acts as a cathode contact point for the diode 100. The inner contact 112 is connected to the P-type doping area of the back 104 side and acts as an anode contact point for the diode 100. Each of the bounded regions (e.g., 112) in an array of such regions can act as a discrete pixel. For example, the regions 112 can each represent a pixel providing a color-sensing element in a color imager or a magnitude-sensing element in a monochromatic or gray-scale imager.

In the exemplary embodiment, the anode contact 112 is electrically isolated from the cathode contact 110. A diode using a back side contact configuration allows for single sided fabrication, reducing cost and reducing complexity of manufacture. Also, a diode using a back side contact configuration may be substantially fully fabricated before the laser step process is performed. Fabrication before the laser step removes the need to re-enter the material into the foundry after the laser step, eliminating the contamination risk typically associated with the re-entry of partially processed material and increasing the number of available fabrication partners.

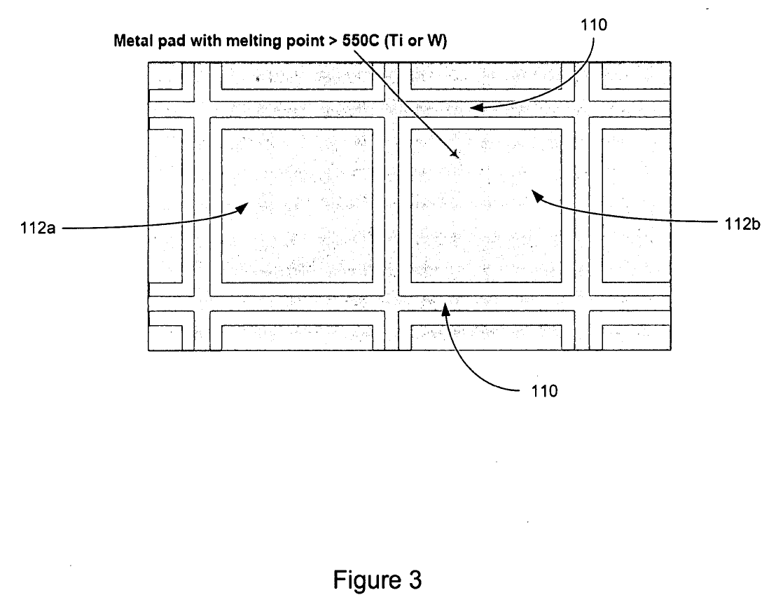

FIG. 3 illustrates an exemplary array of laser treated semiconductor diodes with back-side metal contact pads. In the exemplary embodiment, the cathode contacts 110 are all electrically connected and form a common-cathode configuration. In the exemplary embodiment, the cathode and anode connections are arranged in a grid pattern where the cathode contact 10 is configured in a square grid pattern and the anode contacts 112a and 112b are configured as individual square contacts within the cathode grid pattern 110. An array using the above configuration may be vertically bonded to readout circuitry and create a fully functional imager.

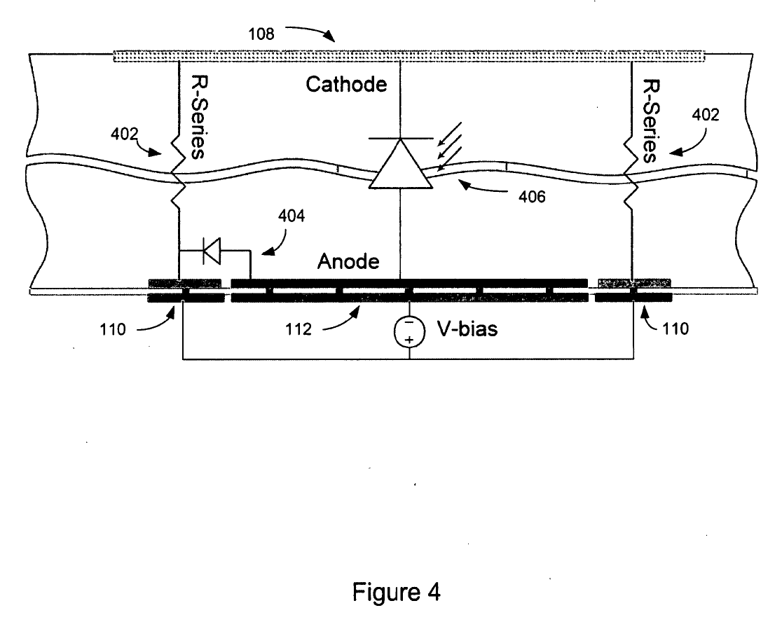

FIG. 4 illustrates a cross sectional area of an exemplary embodiment of a laser treated semiconductor diode with back-side metal contact pads including an exemplary circuit diagram approximation of the diode in operation. During operation, the cathode contact 110 may be positively biased in relation to the anode contact 112. The bias voltage (“V-bias”) can be about 1 to 10 volts in some embodiments. In some embodiments the bias voltage can be about 3 to 5 volts. In some embodiments, the required bias voltage is substantially less than that in corresponding conventional devices. When the cathode is sufficiently positively biased, it will create an electric field that extends through the bulk layer 106 to the laser treated semiconductor layer 108 on the front 102 side, attracting the mobile electrons and depleting the laser treated semiconductor layer 108. The anode contact 112 is held negative with respect to the cathode contact 110 and the laser treated semiconductor layer 108. During operation, the bulk layer 106 may be modeled as a series resistance 402 between the cathode contact 110 and the laser treated semiconductor layer 108. While the electric field generated between the anode and the cathode by their P-N junction 404 has a small relative volume, the field generated by the P-N junction 406 between the laser treated semiconductor layer 108 and the anode contact 112 has a larger, or even significantly larger volume. Therefore, electron hole/pairs generated by photon absorption at or near the laser treated semiconductor layer 108 are separated in this field. The electrons travel to the cathode contact 110 through the laser treated semiconductor layer 108, while the holes travel to the anode contact 112 through the field established by the P-N junction 406 between the laser treated semiconductor layer 108 and the anode contact 112.

While the exemplary diode shown was a P-N junction type diode, many other diode types may be implemented as discussed above, including Schottky diodes and P-type implementations. The p-type implementation may be implemented by reversing the dopant type throughout the diode and reversing the bias applied to the diode during use. The P-type implementation will function similarly to the N-type implementation except that the electron and hole flow paths will reverse direction.

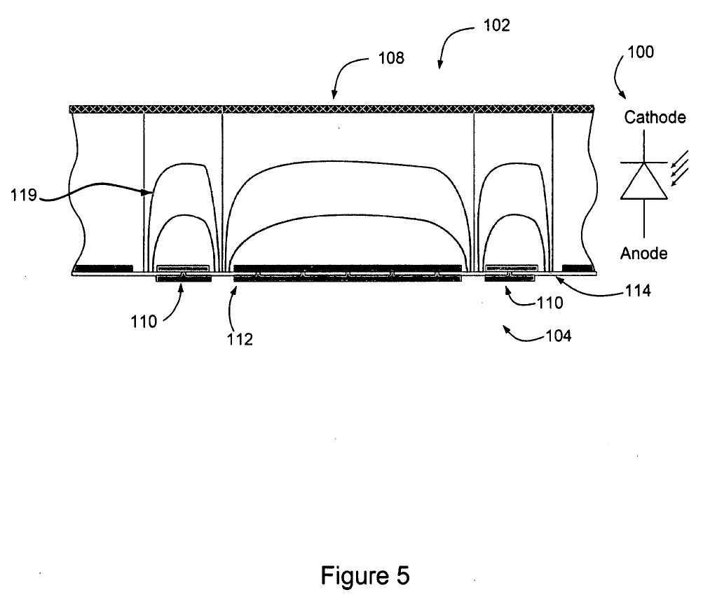

FIG. 5 illustrates an exemplary diagram of the field lines 119, in a cross sectional area during operation of a laser treated semiconductor diode with back-side metal contact pads. Each field line represents a contour of equal voltage, or representing lines of equipotential. A tighter spacing of field lines indicates a stronger electromagnetic field.

I claim:

1. A photosensing semiconductor device, comprising:
a bulk semiconductor material being doped with a first dopant and a second dopant comprising:
a laser treated region being doped with said first dopant;
a region being doped with said second dopant, said region being electrically coupled with said laser treated region thereby forming a diode;
a first ohmic contact in contact with said region being doped with said second dopant; and
a second ohmic contact in electrical communication with said laser treated region via the bulk semiconductor material.

2. The device of claim 1, wherein the bulk semiconductor material is comprised of silicon.

3. The device of claim 1, wherein said first dopant is an N-type dopant.

4. The device of claim 3, wherein the N-type dopant is sulfur.

5. The device of claim 1, wherein the electrical communication is induced by the electrical field created within the bulk semiconductor material.

6. The device of claim 1, further comprising an absorption region extending from a surface into the bulk semiconductor material.

7. The device of claim 6, wherein the device has a fill factor greater than 90%.

8. The device of claim 1, wherein the bulk semiconductor material has a thickness of less than about 500 μm.

9. The device of claim 1, wherein the bulk semiconductor material has a thickness of less than about 100 μm.

10. The device of claim 1, wherein the bulk semiconductor material has a thickness of less than about 50 μm.

11. The device of claim 1, wherein the laser treated region is on a frontside of the device such that radiation is directly incident on said laser treated region.

12. The device of claim 1, wherein the laser treated region is on a backside of the device such that radiation penetrates the device prior to contact with laser treated region.

13. An array of photosensing semiconductor devices comprising:
a plurality of photosensing devices each comprising:
a bulk semiconductor material being doped with a first dopant and a second dopant comprising:
a laser treated region being doped with said first dopant;
a region being doped with said second dopant, said region being electrically coupled with said laser treated region thereby forming a diode;
a first ohmic contact in contact with said region being doped with said second dopant; and
a second ohmic contact in electrical communication with said laser treated region via the bulk semiconductor material.

14. The photosensing array of claim 13, further comprising a top surface that is substantially contiguous between the plurality of devices.

15. The photosensing array of claim 13, where in the top surface has an absorption fill factor of greater than about 90%.

16. A method of making a photosensing device comprising the steps of:
providing a bulk semiconductor material;
lasing the bulk semiconductor material;
annealing at least a portion of the bulk semiconductor material;
depositing a metal layer on the bulk semiconductor material on the opposite from the lased side.

17. The method of claim 16, wherein the metal layer is electrically connected to the bulk semiconductor material via a contact dopant layer.

18. The method of claim 17, wherein the contact dopant layer is deposited or implanted.

19. A method of making a photosensing device comprising the steps of:
providing a bulk semiconductor material;
depositing a metal layer on the bulk semiconductor material lasing a side of the bulk semiconductor material that is devoid of the metal layer;
annealing at least a portion of the bulk semiconductor material;
